(19) United States
(12) Patent Application Publication
(10) Pub. No.: US 2018/0019194 A1
(43) Pub. Date: Jan. 18, 2018

(54) Low Parasitic Surface Mount Circuit Over Wirebond IC

(71) Applicant: Semtech Corporation, Camarillo, CA (US)

(72) Inventor: Jean-Marc Papillon, Ottawa (CA)

(73) Assignee: Semtech Corporation, Camarillo, CA (US)

(21) Appl. No.: 15/647,631

(22) Filed: Jul. 12, 2017

Related U.S. Application Data
(60) Provisional application No. 62/362,501, filed on Jul. 14, 2016.

(51) Int. Cl. H01L 23/498; H01L 23/48; H01L 21/56; H01L 23/52; H01L 23/31

(52) U.S. Cl. CPC H01L 23/49816; H01L 23/52; H01L 23/3128; H01L 21/563; H01L 23/481; H01L 2924/15311; H01L 2924/19107

(57) ABSTRACT

A semiconductor device has an interposer and a surface mount technology (SMT) component disposed on the interposer. The interposer is disposed on an active surface of a semiconductor die. The semiconductor die is disposed on a substrate. A first wire bond connection is formed between the interposer and semiconductor die. A second wire bond connection is formed between the interposer and substrate. A third wire bond connection is formed between the substrate and semiconductor die. An encapsulant is deposited over the substrate, semiconductor die, interposer, and SMT component. In one embodiment, the substrate is a quad flat non-leaded substrate. In another embodiment, the substrate is a land-grid array substrate, ball-grid array substrate, or leadframe.

### CLAIM TO DOMESTIC PRIORITY

The present application claims the benefit of U.S. Provisional Application No. 62/362,501, filed Jul. 14, 2016, which application is incorporated herein by reference.

### FIELD OF THE INVENTION

The present invention relates in general to semiconductor devices and, more particularly, to a semiconductor device and method of vertically integrating passive circuits over a wire-bond packaged integrated circuit (IC).

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

One goal of semiconductor manufacturing is to produce smaller semiconductor devices. Smaller devices, and the resulting smaller end products, typically consume less power, can be produced more efficiently, and have higher performance. Smaller semiconductor devices and smaller end products consume less materials in manufacturing which reduces environmental impact. In addition, smaller semiconductor devices have a smaller footprint, which is desirable for crowded printed circuit boards and smaller end products demanded by consumers. A smaller die size may be achieved by improvements in the front-end process resulting in die with smaller, higher density active and passive components. Back-end processes may result in semiconductor device packages with a smaller footprint by improvements in electrical interconnection and packaging materials.

Some IC designs require low parasitic interconnection, which is not easily achievable within the IC, nor by using common redistribution layers (RDL) on or over the IC. Because of die layout congestion, electrical isolation requirements, or signal integrity requirements, contact pads at remote locations of a semiconductor die may be connected to each other externally, e.g., using bond wires.

However, bond wires have relatively high parasitic electrical characteristics that are hard to control. In addition, many semiconductor devices require passive components with larger values, or manufactured to a tighter tolerance, than can be easily formed on or within layers of a semiconductor die.

Discrete passive devices are commonly disposed on a substrate adjacent to a semiconductor die to provide the needed discrete passive components. The discrete passive devices are connected to the substrate by solder or conductive epoxy. A conductive trace on the substrate connects the discrete passive device to a bond pad, which is then connected to the semiconductor die by a bond wire. The larger substrate required to hold both a semiconductor die and passive devices increases the total package size of the end semiconductor device. Moreover, the bond wires required to connect the terminals of a passive network are typically relatively long to connect from the semiconductor die to passive components disposed adjacent to the semiconductor die on a common substrate. The external passive components and bond wire interconnections increase package size and introduce undesirable parasitic electrical characteristics.

A need exists to provide surface mount technology (SMT) components along with a semiconductor die, in a small footprint package with improved parasitic characteristics.

### BRIEF DESCRIPTION OF THE DRAWINGS

FIG. 1 illustrates an interposer or secondary substrate;

FIG. 2 illustrates a semiconductor die;

FIG. 3 illustrates a leadframe substrate;

FIG. 4 illustrates the interposer and semiconductor die stacked over the leadframe substrate;

FIGS. 5a-5d illustrate signal paths formed over the interposer;

FIG. 6 illustrates a semiconductor die disposed on the interposer;

FIG. 7 illustrates a final semiconductor device encapsulated for environmental protection; and

FIGS. 8a-8b illustrate an electronic device incorporating the final semiconductor device.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, those skilled in the art will appreciate that the description is intended to cover alternatives, modifications, and equivalents as may be included within the spirit and scope of the invention as defined by the appended claims and the claims' equivalents as supported by the following disclosure and drawings.

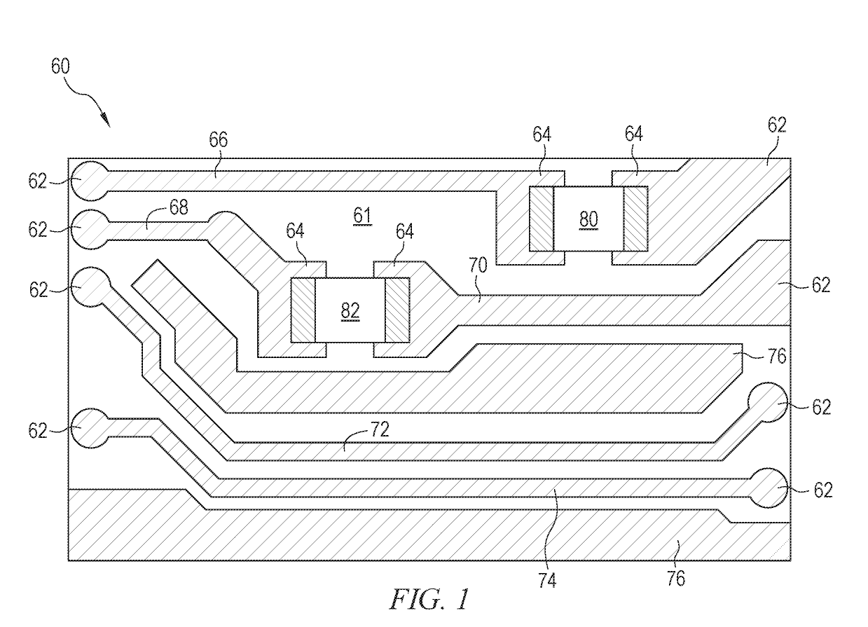

FIG. 1 illustrates an interposer 60, configured to be disposed on an active surface of a semiconductor die, with a top surface of the interposer oriented toward the viewer. Interposer 60 is formed from a base dielectric material 61 that includes one or more laminated layers of polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics. In one embodiment, base material 61 is a composite with woven fiber and filler. Alternatively, base material 61 includes other types of dielectric material, such as a ceramic. Base material 61 is selected to be able to support conductive traces, wire bond pads, and surface mount technology (SMT) pads.

In FIG. 1, interposer 60 includes wire bond pads 62 and SMT pads 64. Conductive traces 66, 68, 70, 72, and 74 electrically connect bonds pads 62 and SMT pads 64 to each other. SMT pads 64 are configured to have SMT components 80 and 82 mounted on interposer 60 via the SMT pads. In the illustrated embodiment, SMT components 80 and 82 are capacitors, e.g., 0201 solderable ceramic capacitors, but other passive SMT components, such as inductors, resistors, or antennae are used in other embodiments. In some embodiments, active SMT components are provided, such as diodes, power MOSFETs, or other semiconductor die or packages. SMT components may be disposed on interposer 60 before or after the interposer is singulated and disposed onto a semiconductor die. SMT components 80 and 82 are attached to SMT pads 64 by solder, conductive epoxy, or another appropriate mechanism.

Bond pads 62, SMT pads 64, and conductive traces 66-74 are formed as a single conductive layer on base material 61 using a patterning and metal deposition process such as printing, PVD, CVD, sputtering, electrolytic plating, or electroless plating. Bond pads 62, SMT pads 64, and conductive traces 66-74 include one or more layers of Al, Cu, Sn, Ni, Au, Ag, or other suitable electrically conductive material. In some embodiments, an insulating or passivation layer is formed over interposer 60 after formation of the conductive layer, with openings in the passivation layer for subsequent connection of SMT components 80-82 to SMT pads 64 and bond wires to bond pads 62. In one embodiment, a multi-layer interposer 60 is used to provide conductive traces that cross signal paths within the layers of the interposer.

Conductive trace 66 couples capacitor 80 in series between the left and right ends of interposer 60 as illustrated. Conductive traces 68 and 70 couple capacitor 82 in series between the left and right ends of interposer 60. Capacitors 80 and 82 can be coupled between points on opposite sides of an underlying semiconductor die or substrate through interposer 60. Interposer 60 provides a low parasitic connection due to bond pads 62 being placed in close proximity to contact pads on an underlying substrate or semiconductor die. Bond wires from bond pads 62 to contact pads on an underlying semiconductor die or substrate are relatively short, and thus have good parasitic properties, due to interposer 60 being placed in a central area of the semiconductor die or substrate.

Conductive traces 72 and 74 form a differential pair transmission line from a left side of interposer 60, as illustrated, to the right side. Traces 72 and 74 allow a balanced signal to be transmitted across the length or width of an underlying semiconductor die or substrate with a controlled impedance and low parasitic characteristics. Impedance is controlled by ground traces 76 flanking the differential pair formed by traces 72 and 74, as well as a ground plane formed under the differential pair. Ground traces 76 are formed surrounding traces 72 and 74 to reduce interference from adjacent traces and help control impedance of the transmission line. Ground traces 76 are connected to each other by conductive vias under the ground traces that extend through base material 61, and a conductive ground plane formed on the bottom surface, or an intermediate layer, of interposer 60 below traces 72 and 74. Conductive traces also form microstrip or other types of transmission lines across interposer 60 in other embodiments. In one embodiment, conductive traces form one or more antennae on interposer 60.

Bond pads 62 are configured to have bond wires attached to the bond pads during subsequent manufacturing steps. Bond pads 62 are formed near edges of the interposer to reduce the length of bond wires used to connect an underlying semiconductor die or substrate to the bond pads. Shorter bond wires reduce parasitic electrical characteristics of a final semiconductor device formed using interposer 60.

SMT pads 64 are configured to couple capacitors 80 and 82 between bond pads on opposite sides of interposer 60. In other embodiments, conductive traces, SMT pads, and SMT components are configured to form low-pass filters or other more complicated passive networks for radio frequency (RF) signal processing and other applications. Conductive traces are formed over the top surface, bottom surface, and intermediate layers of base material 61 as needed to connect passive components in series and parallel between bond pads 62 to form a desired passive network.

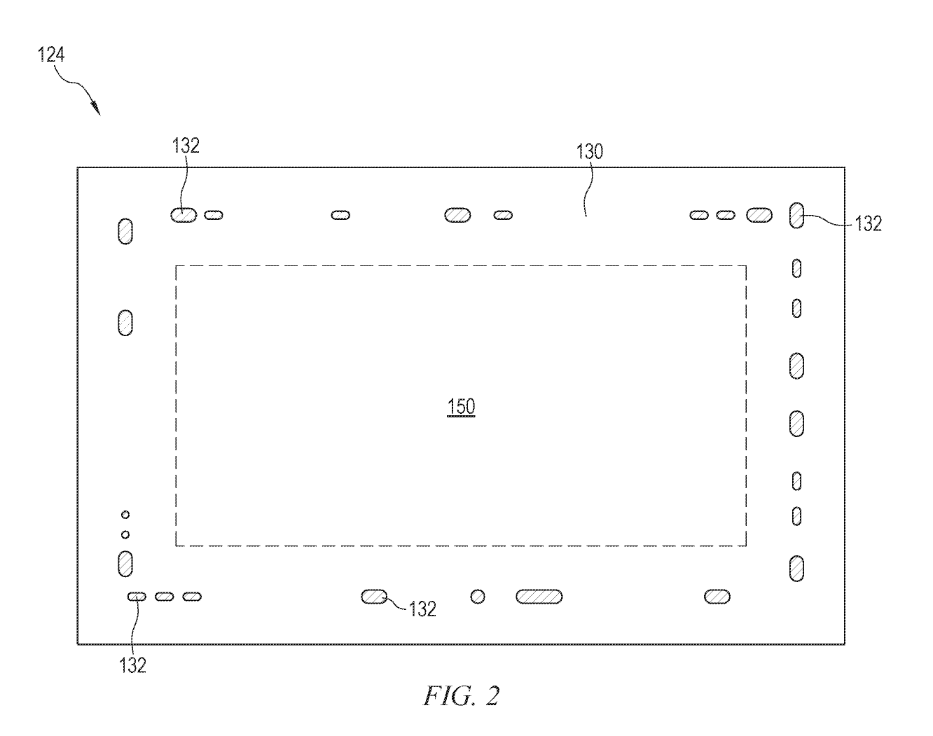

FIG. 2 illustrates semiconductor die 124 with an active surface 130 of the semiconductor die facing the viewer. Contact pads 132 are formed on or over active surface 130 while a central area 150 is left void of contact pads. Contact pads 132 form a ring around central area 150. Central area 150 is configured to have interposer 60 disposed on active surface 130 within the central area with sufficient room around the interposer for bond wires attached to contact pads 132. In some embodiments, interposer 60 is disposed over an area of semiconductor die 124 devoid of contact pads that is not necessarily centrally located on the semiconductor die. Contact pads 132 are configured to have bond wires coupled between contact pads 132 on the semiconductor die and bond pads 62 on interposer 60 once the interposer is disposed in central area 150. Active surface 130 contains analog or digital circuits implemented as active devices, passive devices, conductive layers, and dielectric layers formed on and within the die and electrically interconnected according to the electrical design and function of the die. The circuits of active surface 130 are connected to contact pads 132 for subsequent connection to interposer 60 and other external circuit elements by bond wires.

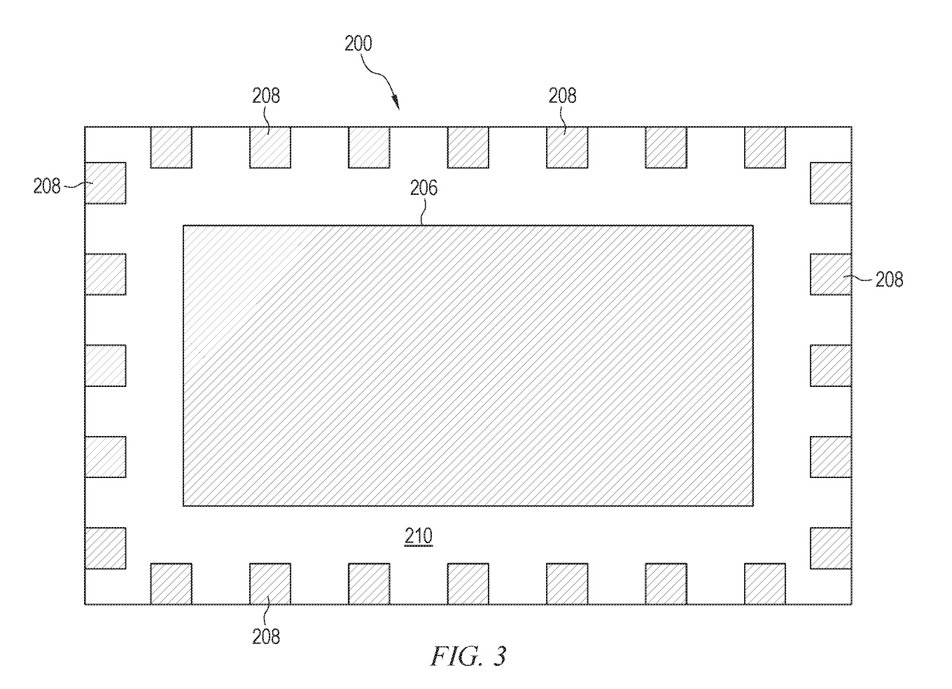

FIG. 3 illustrates a quad-flat non-leaded (QFN) substrate 200. QFN substrate 200 includes a centrally located die paddle 206 for supporting semiconductor die 124 on the QFN substrate. A plurality of electrical terminals or contacts 208 are disposed around die paddle 206. Die paddle 206 and contacts 208 form a QFN leadframe. Semiconductor die 124 is disposed on die paddle 206 and electrically connected to contacts 208 by bond wires. In some embodiments, encapsulant 210 is disposed over die paddle 206 and contacts 208 to form a substrate for semiconductor die 124. In other embodiments, semiconductor die 124 and interposer 60 are disposed on die paddle 206 without encapsulant 210. Then, leadframe 200, semiconductor die 124, and interposer 60 are all encapsulated together at a later step. While a QFN leadframe is illustrated, a land grid array (LGA), ball-grid array (BGA), quad flat package (QFP), or other suitable package leadframe or substrate is used in other embodiments.

Contacts 208 remain exposed at top, side, and bottom surfaces of QFN substrate 200. The top surfaces of contacts 208, facing the viewer in FIG. 3, accommodate bond wire connections to contact pads 132 of semiconductor die 124 and bond pads 62 of interposer 60. Contacts 208 remain exposed at bottom and side surfaces for subsequent interconnection of the final device to a printed circuit board (PCB) or other larger substrate using solder or another appropriate mechanism.

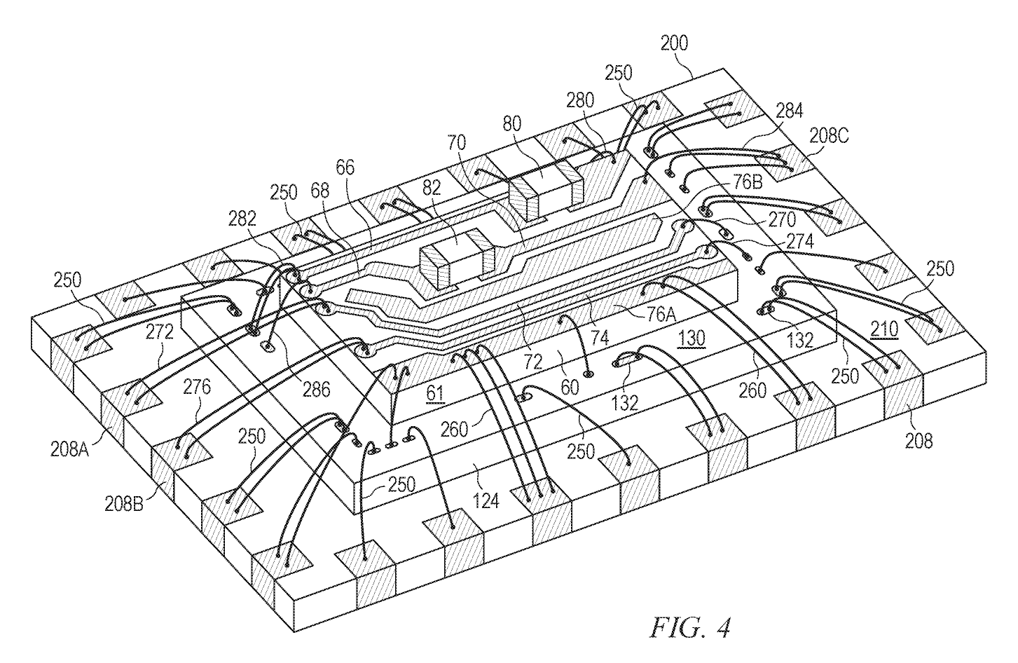

In FIG. 4, semiconductor die 124 from FIG. 2 and interposer 60 from FIG. 1 are stacked over or disposed on QFN substrate 200 from FIG. 3. In one embodiment, interposer 60 is disposed on central area 150 of semiconductor die 124 while the semiconductor die remains in wafer form, prior to singulation. In other embodiments, a singulated semiconductor die 124 is disposed on die paddle 206, followed by interposer 60 being disposed on active surface 130. Substrate 200 provides a substrate for the package as a whole, while interposer 60 is a secondary substrate for SMT components and transmission lines.

In some embodiments, a die-attach adhesive, such as glue or double-sided tape, is deposited over central area 150 of semiconductor die 124, or the back surface of interposer 60, prior to disposing the interposer onto the semiconductor die. The adhesive can include epoxy resin, thermoplastic resin, acrylate monomer, a hardening accelerator, organic filler, silica filler, or polymer filler. In one embodiment, an adhesive film or paste is used. Using an adhesive facilitates and strengthens the attachment of interposer 60 to semiconductor die 124. A similar adhesive is used for attaching semiconductor die 124 to QFN substrate 200 in some embodiments.

Bond wires are formed between contacts 208 of substrate 200, contact pads 132 of semiconductor die 124, and bond pads 62 of interposer 60. The bond wires are wedge bonded or stud bumped conductive wires. The bond wires are formed of copper, gold, or other metal alloy wire as a three-dimensional interconnection. Bond wires 250 are formed between contacts 208 of substrate 200 and contact pads 132 of semiconductor die 124. Bond wires 250 extend electrical connection from circuit terminals on active surface 130 to allow external interconnection at contacts 208 that are exposed from the final device. Bond wires 260 connect contacts 208 that operate as ground terminals to ground trace 76A. Several bond wires 260 are connected in parallel from ground terminal contacts 208 to ground trace 76A to improve the ground connection electrical current handling capability. Ground trace 76B is coupled to ground trace 76A by conductive vias formed through base material 61 and a ground plane formed on the bottom surface, or in an intermediate layer, of interposer 60.

Bond wires 272 are coupled between contact 208A and conductive trace 72 at a first end of conductive trace 72. Bond wire 270 couples the second end of conductive trace 72 to a contact pad 132 on the opposite side of semiconductor die 124 from contact 208A. Bond wires 276 electrically couple contact 208B to a first end of conductive trace 74. Bond wire 274 couples the second end of conductive trace 74 to a contact pad 132 on the opposite side of semiconductor die 124 from contact 208B. Contacts 208A and 208B are external terminals allowing the communication of a balanced electrical signal to or from semiconductor die 124. A balanced electrical signal at contacts 208A and 208B is transmitted to the opposite side of semiconductor die 124 with a controlled impedance and low parasitic properties through transmission lines of traces 72 and 74. Traces 72 and 74 also transmit a balanced signal from semiconductor die 124 to an external system at contacts 208A and 208B in another embodiment. Using conductive traces 72 and 74 to route electrical signals across almost the entire surface area of semiconductor die 124 improves electrical parasitics and routing clutter relative to connecting directly across the semiconductor die with bond wires.

Bond wires 282 connect conductive trace 66 to a contact pad 132 on semiconductor die 124. Bond wire 280 connects the terminal of capacitor 80 opposite conductive trace 66 to another contact pad 132. Conductive trace 66 and bond wires 280-282 connect a contact pad 132 near capacitor 80 to a reference voltage at a remote contact pad 132. Capacitor 80 and trace 66 provide decoupling of a signal on semiconductor die 124 from a reference voltage at a remote location of the semiconductor die.

Bond wire 286 connects conductive trace 68 of interposer 60 to a contact pad 132 on semiconductor die 124. Bond wire 284 connects conductive trace 70 to contact 208C on a side of substrate 200 opposite bond wire 286 and trace 68. Capacitor 82 provides decoupling of a signal on semiconductor die 124 from a reference voltage provided by an external signal at contact 208C that is relatively remote from the signal on semiconductor die 124.

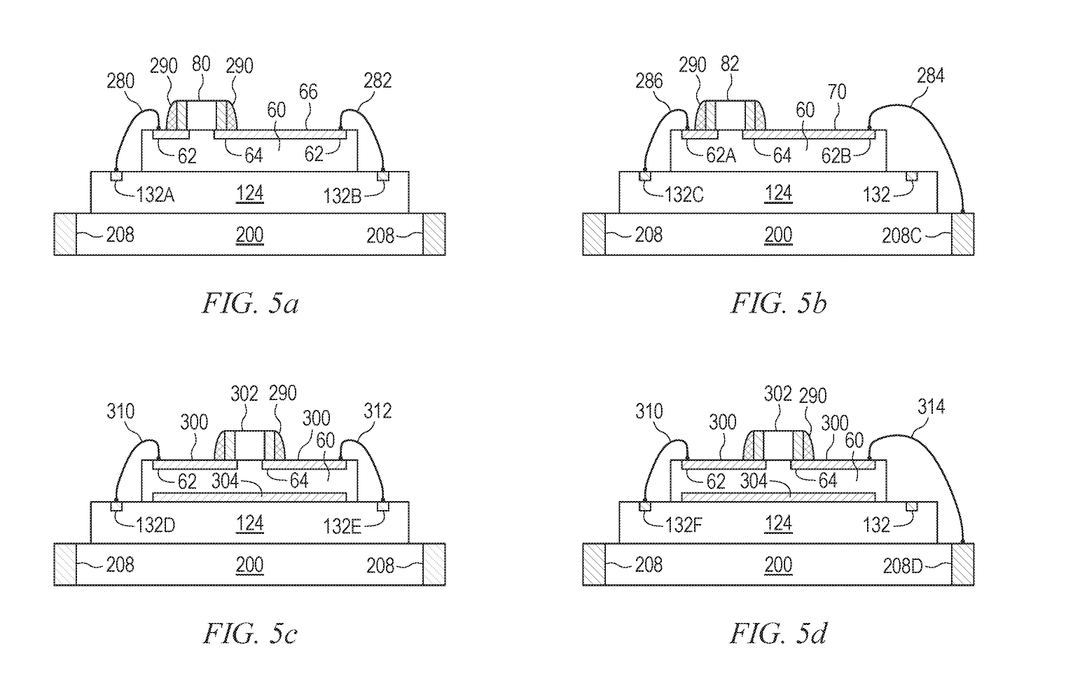

FIGS. 5a-5d illustrate cross-sectional views of substrate 200, semiconductor die 124, and interposer 60 with various non-limiting uses illustrated. FIG. 5a illustrates capacitor 80 from FIG. 4. A first terminal of capacitor 80 is coupled to contact pad 132A of semiconductor die 124 by bond wire 280. A second terminal of capacitor 80 is coupled to contact pad 132B of semiconductor die 124 by conductive trace 66 and bond wire 282. Capacitor 80 provides decoupling for a signal at contact pad 132A from a reference voltage at contact pad 132B. Contact pads 132A and 132B are at remote locations of semiconductor die 124, but are connected to capacitor 80 by low parasitic connections due to the close proximity of bond pads 62 to contact pads 132A and 132B. Solder or other conductive material 290 mechanically bonds and electrically connects terminals of capacitor 80 to SMT pads 64.

FIG. 5b illustrates capacitor 82 from FIG. 4 coupled between contact pad 132C on semiconductor die 124 and contact 208C of substrate 200. Bond wire 286 couples a first terminal of capacitor 82 to contact pad 132C. Bond wire 286 provides a low parasitic connection because the close proximity of contact pad 132C to bond pad 62A allows a relatively short bond wire 286 to be used. The second terminal of capacitor 82 is coupled to contact 208C by conductive trace 70 and bond wire 284. Bond wire 284 extends directly from bond pad 62B to contact 208C to provide a low parasitic connection to capacitor 82. Capacitor 82 decouples a signal at contact pad 132C from an external reference voltage provided at contact 208C. Contact pad 132C and contact 208C are on opposite sides of the device, but are connected through capacitor 82 and conductive trace 70 with a low parasitic connection due to usage of interposer 60 over active surface 130 of semiconductor die 124.

FIG. 5c illustrates a high-speed transmission line 300 formed across interposer 60 between remote areas of semiconductor die 124. An SMT capacitor 302 is coupled in series along transmission line 300 for alternating current (AC) coupling. A more complex passive network is used for RF processing in other embodiments. In some embodiments, direct current (DC) coupled transmission lines do not use capacitor 302. A ground plane 304 formed on the surface of interposer 60 opposite transmission line 300, or within layers of interposer 60, provides impedance control for the transmission line. Contact pad 132D is coupled to transmission line 300 by bond wire 310. Contact pad 132E is coupled to transmission line 300 by bond wire 312. Contact pad 132D is coupled to contact pad 132E by a low parasitic connection because of the short bond wire connections to interposer 60. Transmission line 300 allows for control of electrical impedance between contact pads 132D and 132E, and capacitor 302 provides AC coupling.

FIG. 5d illustrates transmission line 300 coupled between contact pad 132F of semiconductor die 124 and contact 208D of substrate 200. In FIG. 5d, transmission line 300 provides a controlled impedance and low parasitic connection between contact 208D and contact pad 132F located at relatively remote areas of the package. A signal connected externally at contact 208D is electrically connected to semiconductor die 124 at an opposite side of the package without significant contribution to bond wire congestion or increase of parasitic inductance.

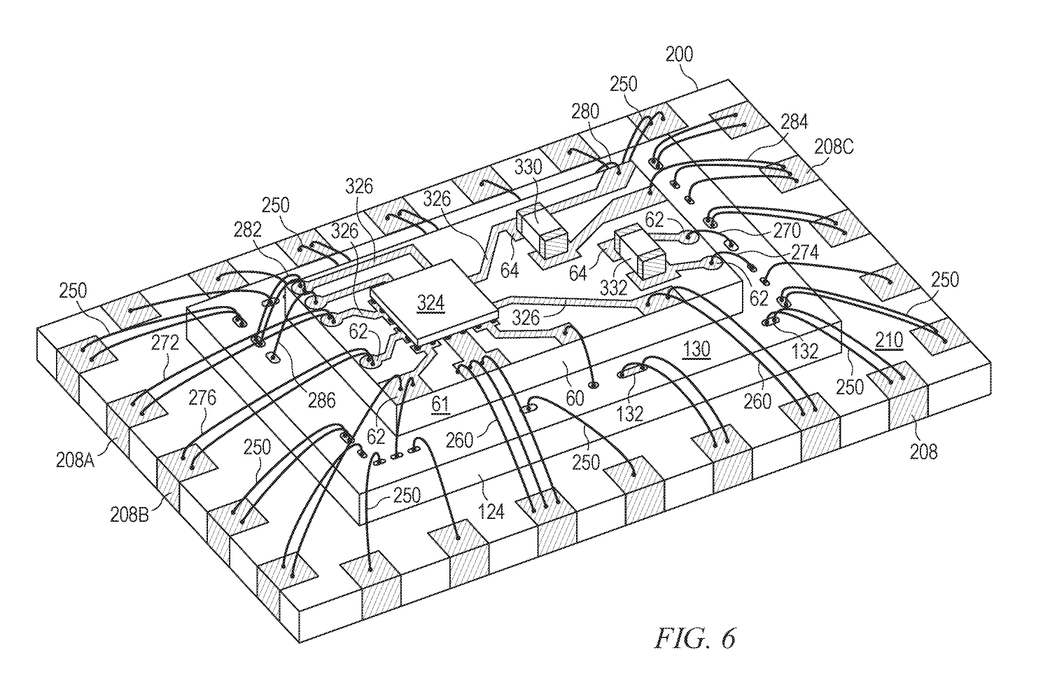

FIG. 6 illustrates an embodiment with a second semiconductor package or bare die 324 flip-chip mounted onto interposer 60. Semiconductor die 324 is an active device with one or more transistors, diodes, etc. formed thereon. Semiconductor die 324 provides active functionality to supplement semiconductor die 124. Conductive traces 326 route electrical signals between bond pads 62 around the edges of interposer 60 to semiconductor die 324 and SMT pads 64. Solder bumps or other interconnect structures extend from semiconductor die 324 to contact pads of interposer 60 underneath the semiconductor die. The bond wires electrically couple bond pads 62 on interposer 60 to contact pads 132 on semiconductor die 124 and contacts 208 of substrate 200 as necessary to implement desired electrical functions.

Capacitor 330 is coupled between a conductive trace 326 to semiconductor die 324 and a contact 208. Capacitor 332 is coupled between two contact pads 132 of semiconductor die 124 via bond wires 270 and 274. Capacitor 332 is integrated into the circuitry on active surface 130. Being a discrete component allows capacitor 332 to have a higher capacitance value than can normally be attained using normal manufacturing methods on active surface 130. Being on interposer 60, which is disposed directly on active surface 130, brings capacitor 332 within close proximity of contact pads 132. Bond wires 270 and 274 between contact pads 132 and bond pads 62 are significantly shorter than would otherwise be necessary without interposer 60.

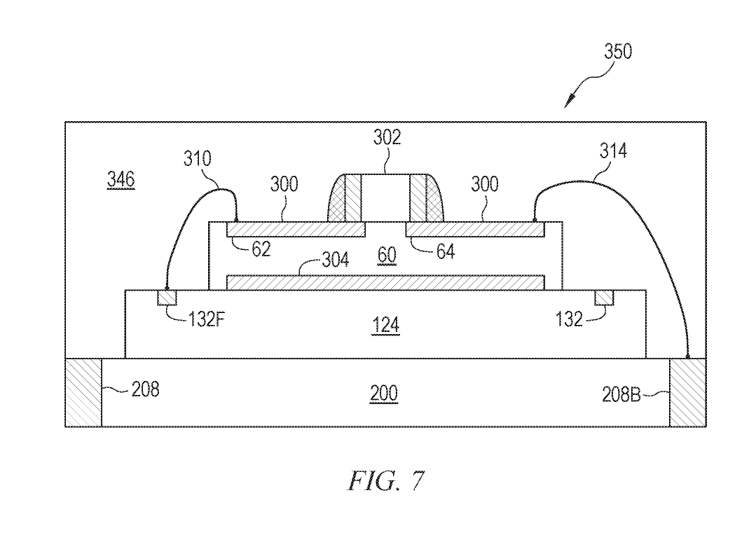

In FIG. 7, an encapsulant or molding compound 346 is deposited over leadframe 200, semiconductor die 124, interposer 60, SMT components 80-82 and 302, bond wires 250-286, and bond wires 310-314 as an insulating material using a paste printing, compressive molding, transfer molding, liquid encapsulant molding, vacuum lamination, spin coating, or other suitable applicator to create a final semiconductor package or device 350. In one embodiment, encapsulant 346 is deposited using tape assisted transfer molding. Encapsulant 346 can be polymer composite material, such as epoxy resin with filler, epoxy acrylate with filler, or polymer with proper filler. Encapsulant 346 is non-conductive and environmentally protects the semiconductor device from external elements and contaminants. Encapsulant 346 also protects semiconductor die 124 from degradation due to exposure to light. In some embodiments, a plurality of semiconductor devices 350 is encapsulated in a single step, and then singulated using a saw blade or laser cutting tool to separate the semiconductor devices. In another embodiment, a hermetically sealed lid is disposed over substrate 200, semiconductor die 124, and interposer 60 to complete package 350. In some embodiments a ceramic style package is hermetically sealed using a lid.

Semiconductor device 350 provides a semiconductor die 124 packaged together with SMT components in a small footprint by taking advantage of central area 150 of semiconductor die 124. Contact pads 132 of semiconductor die 124 are located in close proximity to bond pads 62 of interposer 60, allowing relatively short bond wires to couple semiconductor die 124 to SMT components on the interposer. Interposer 60 allows low-loss transmission line routing, controlled impedance line routing, and soldering of conventional SMT components between remote areas of semiconductor die 124. Interposer 60 is made of organic laminate or other economical material. Semiconductor die 124 with interposer 60 is mounted on any wire-bondable die, BGA or LGA substrate, QFN leadframe, or other typical leadframe. The stacked leadframe or substrate 200, semiconductor die 124, and interposer 60 are encapsulated within a package body using conventional molding, dispensing, or capping techniques to form a semiconductor package 350.

Semiconductor package 350 offers package space reduction by relocating SMT components onto a region of the semiconductor package that is non-critical to the package footprint. Wire bond distance is reduced from semiconductor die 124 to SMT components, thus reducing parasitic electrical characteristics. Additionally, contact pads 132 of semiconductor die 124 are connected to each other with controlled impedance and low parasitic electrical characteristics without adding significantly to wire routing congestion in the periphery of semiconductor die 124. Providing interposer 60 as a multi-layer substrate allows signal crossing without the manufacturing difficulty of crossing bond wires.

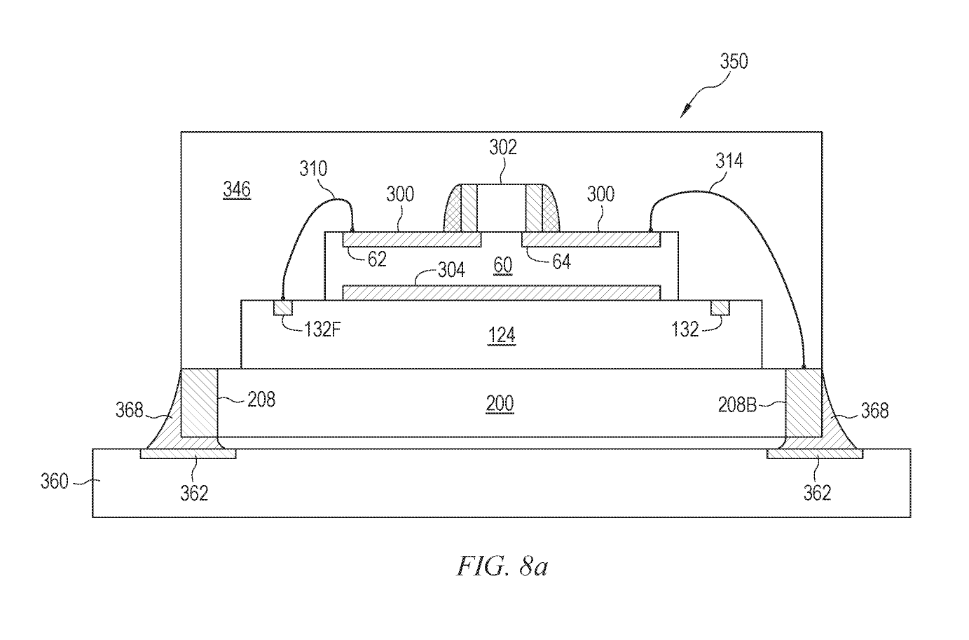

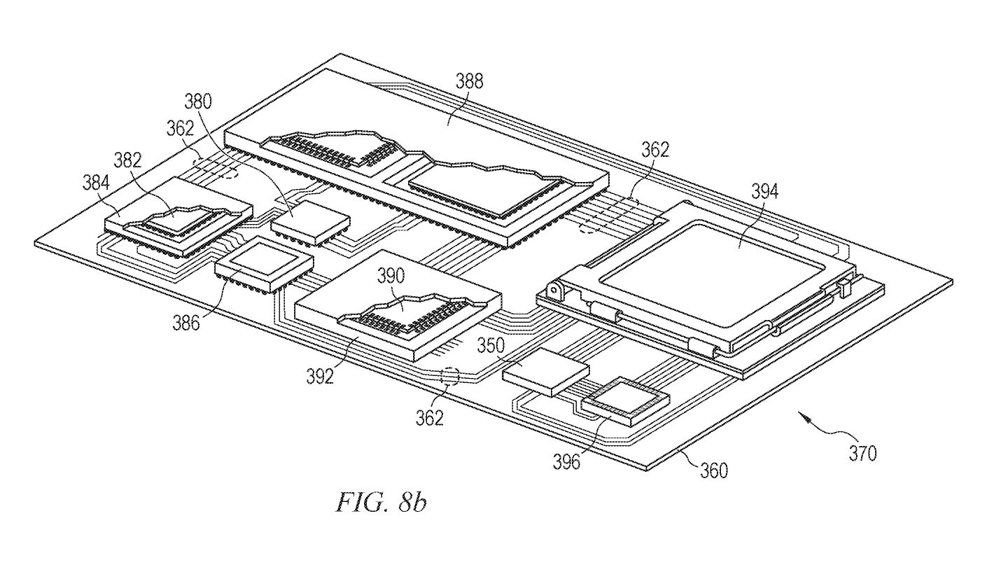

FIG. 8a illustrates semiconductor device 350 mounted onto a PCB or other electronic device substrate 360. Contacts 208 of semiconductor device 350 are electrically and mechanically coupled to conductive layer 362 on PCB 360 by solder 368. In some embodiments, a solder paste is printed onto contact pads of conductive layer 362 and then reflowed onto the bottom and side surfaces of contacts 208. In other embodiments, semiconductor device 350 is disposed on PCB 360 and then solder is applied. An adhesive layer is disposed between substrate 200 and PCB 360 if desired.

FIG. 8b illustrates semiconductor package 350, with substrate 200, semiconductor die 124, and interposer 60, integrated into an electronic device 370 having a chip carrier substrate or PCB 360 with a plurality of semiconductor packages mounted on a surface of the PCB along with semiconductor package 350. Electronic device 370 can have one type of semiconductor package, or multiple types of semiconductor packages, depending on the application.

Electronic device 370 can be a stand-alone system that uses the semiconductor packages to perform one or more electrical functions. Alternatively, electronic device 370 can be a subcomponent of a larger system. For example, electronic device 370 can be part of a tablet, cellular phone, digital camera, communication system, or other electronic device. Alternatively, electronic device 370 can be a graphics card, network interface card, or other signal processing card that can be inserted into a computer. The semiconductor packages can include microprocessors, memories, ASIC, logic circuits, analog circuits, RF circuits, discrete devices, or other semiconductor die or electrical components.

In FIG. 8b, PCB 360 provides a general substrate for structural support and electrical interconnect of the semiconductor packages mounted on the PCB. Conductive signal traces 362 are formed over a surface or within layers of PCB 360 using evaporation, electrolytic plating, electroless plating, screen printing, or other suitable metal deposition process. Signal traces 362 provide for electrical communication between each of the semiconductor packages, mounted components, and other external system components. Traces 362 also provide power and ground connections to the semiconductor packages as needed.

For the purpose of illustration, several types of first level packaging, including bond wire package 390 and flipchip 382, are shown on PCB 360. Additionally, several types of second level packaging, including ball grid array (BGA) 384, bump chip carrier (BCC) 392, land grid array (LGA) 394, multi-chip module (MCM) 388, quad flat non-leaded package (QFN) 396, embedded wafer level ball grid array (eWLB) 386, and wafer level chip scale package (WLCSP) 380 are shown mounted on PCB 360. In one embodiment, eWLB 386 is a fan-out wafer level package (Fo-WLP) or fan-in wafer level package (Fi-WLP). Depending upon the system requirements, any combination of semiconductor packages, configured with any combination of first and second level packaging styles, as well as other electronic components, can be connected to PCB 360.

In some embodiments, electronic device 370 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing an interposer;
disposing a surface mount component over the interposer;
providing a semiconductor die;
disposing the interposer over the semiconductor die; and
forming a first bond wire between the interposer and semiconductor die.

2. The method of claim 1, further including:
providing a package substrate; and
disposing the semiconductor die over the package substrate.

3. The method of claim 2, further including forming a second bond wire between the package substrate and the interposer.

4. The method of claim 1, further including:
forming a transmission line over the interposer, wherein the first bond wire is coupled to a first end of the transmission line; and
forming a second bond wire coupled to a second end of the transmission line.

5. The method of claim 4, further including coupling the transmission line and surface mount component in series between the first bond wire and second bond wire.

6. The method of claim 4, further including:
coupling the first bond wire to a first contact pad of the semiconductor die; and
coupling the second bond wire to a second contact pad of the semiconductor die, wherein the first bond pad and second bond pad are adjacent to opposites edges of the interposer.

7. A method of making a semiconductor device, comprising:
providing an interposer;
disposing a surface mount component on the interposer;
providing a semiconductor die; and
disposing the interposer on an active surface of the semiconductor die.

8. The method of claim 7, further including forming a transmission line over the interposer.

9. The method of claim 8, further including:
forming a first bond wire coupled from the semiconductor die to a first end of the transmission line; and
forming a second bond wire coupled from the semiconductor die to a second end of the transmission line.

10. The method of claim 7, further including:
providing a substrate; and
disposing the semiconductor die over the substrate.

11. The method of claim 10, further including forming a wire bond connection between the interposer and substrate.

12. The method of claim 10, further including depositing an encapsulant over the substrate, semiconductor die, and interposer.

13. The method of claim 10, wherein the substrate is a quad flat non-leaded substrate.

14. A semiconductor device, comprising:
a semiconductor die;
an interposer disposed on an active surface of the semiconductor die;
a surface mount component disposed on the interposer; and
a first bond wire coupled between the interposer and semiconductor die.

15. The semiconductor device of claim 14, wherein the semiconductor die includes a ring of contact pads surrounding the interposer.

16. The semiconductor device of claim 14, further including a transmission line formed on the interposer, wherein the first bond wire is coupled to a first end of the transmission line.

17. The semiconductor device of claim 16, further including:
a substrate disposed over the semiconductor die opposite the interposer; and
a second bond wire coupled between the substrate and a second end of the transmission line.

18. The semiconductor device of claim 16, wherein the surface mount component is a capacitor coupled in series with the transmission line.

19. The semiconductor device of claim 14, further including an active circuit component disposed on the interposer.

20. A semiconductor device, comprising:
a semiconductor die;
an interposer disposed on an active surface of the semiconductor die; and
a surface mount component disposed on a surface of the interposer.

21. The semiconductor device of claim 20, further including:
a first bond wire coupled between the interposer and the semiconductor die; and
a second bond wire coupled between the interposer and the semiconductor die, wherein surface mount component is coupled between the first bond wire and second bond wire.

22. The semiconductor device of claim 21, further including a transmission line formed over the interposer and coupled between the first bond wire and second bond wire in series with the surface mount component.

23. The semiconductor device of claim 20, further including a substrate, wherein the semiconductor die is disposed on the substrate.

24. The semiconductor device of claim 23, further including:
a first bond wire coupled between the interposer and the semiconductor die; and
a second bond wire coupled between the interposer and the substrate, wherein the surface mount component is coupled between the first bond wire and second bond wire.

25. The semiconductor device of claim 24, further including a transmission line formed over the interposer and coupled between the first bond wire and second bond wire in series with the surface mount component.
